(19) United States
(12) Patent Application Publication
(10) Pub. No.: US 2026/0056463 A1
(43) Pub. Date: Feb. 26, 2026

(54) HYPERVALENT BISMUTH COMPOUND, RESIST COMPOSITION AND PATTERN FORMING PROCESS

(71) Applicant: Shin-Etsu Chemical Co., Ltd., Tokyo (JP)

(72) Inventors: Kousuke Ohyama, Joetsu-shi (JP); Masaki Ohashi, Joetsu-shi (JP); Shun Kikuchi, Joetsu-shi (JP); Satoshi Kusama, Joetsu-shi (JP)

(73) Assignee: Shin-Etsu Chemical Co., Ltd., Tokyo (JP)

(21) Appl. No.: 19/302,493

(22) Filed: Aug. 18, 2025

(30) Foreign Application Priority Data
Aug. 22, 2024 (JP) 2024-140590

(51) Int. Cl. G03F 7/004; C07F 9/94; G03F 7/00; G03F 7/32

(52) U.S. Cl. CPC G03F 7/0042; C07F 9/94; G03F 7/32; G03F 7/70033

(57) ABSTRACT

A resist composition comprising a hypervalent bismuth compound having formula (1) and a solvent is provided. When processed by photolithography using high-energy radiation, the resist composition exhibits a high sensitivity and resolution. The non-chemically-amplified resist composition exhibits a high sensitivity and resolution when processed by photolithography using high-energy radiation, typically EB and EUV lithography.

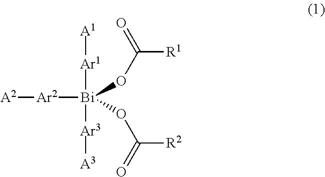

### CROSS-REFERENCE TO RELATED APPLICATION

This non-provisional application claims priority under 35 U.S.C. § 119 (a) on Patent Application No. 2024-140590 filed in Japan on Aug. 22, 2024, the entire contents of which are hereby incorporated by reference.

### TECHNICAL FIELD

This invention relates to a hypervalent bismuth compound, resist composition, and pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the feature size is reduced, image blurs due to acid diffusion become a problem (see Non-Patent Document 1). To insure resolution for fine patterns with a feature size of nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having a polymerizable olefin. With respect to the patterning of a resist film to a feature size of 16 nm et seq., it is believed impossible in the light of acid diffusion to form such a pattern from a chemically amplified resist composition. It would be desirable to have a non-chemically-amplified resist composition.

A typical non-chemically-amplified resist material is polymethyl methacrylate (PMMA). It is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of their application to the resist at a practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 1 discloses a chemically amplified resist composition containing highly EUV-absorbing bismuth atoms. However, as mentioned above, the chemically amplified resist composition cannot reach the resolution desired in the EUV lithography where the pattern feature size becomes smaller than ever.

Patent Document 2 discloses a negative resist composition comprising a tin compound and an organic solvent. Based on tin element having high EUV absorption, this resist composition is improved in stochastics and achieves a high sensitivity and high resolution. The so-called metal resist compositions, however, suffer from many problems including low solubility in resist solvents, poor shelf stability due to excessively high reactivity, and defectiveness due to post-etching residues.

### CITATION LIST

Patent Document 1: JP-A 2018-005224 (U.S. Pat. No. 10,323,113)
Patent Document 2: JP-A 2021-503482
Non-Patent Document 1: SPIE Vol. 5039 p1 (2003)
Non-Patent Document 2: SPIE Vol. 6520 p65203L-1 (2007)

### DISCLOSURE OF INVENTION

An object of the invention is to provide a non-chemically-amplified resist composition which exhibits a high sensitivity and resolution when processed by photolithography using high-energy radiation, typically EB and EUV lithography, and a patterning process using the same.

The inventors have found that a resist composition based on a hypervalent bismuth compound having an aryl group substituted with a polymerizable group forms a resist film having a high sensitivity and satisfactory resolution and is thus quite useful in precise micropatterning.

In one aspect, the invention provides a hypervalent bismuth compound having the formula (1):

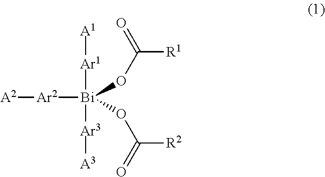

wherein R¹ and R² are each independently halogen or a C₁-C₁₀ hydrocarbyl group which may contain a heteroatom, R¹ and R² may bond together to form a ring with the carbon atoms to which they are attached and the intervenient atoms,
A¹, A² and A³ are each independently a C₂-C₂₀ hydrocarbyl group which contains a polymerizable functional group and may contain a heteroatom,
Ar¹, Ar² and Ar³ are each independently a C₆-C₂₀ arylene group in which some or all of the hydrogen atoms on an aromatic ring may be substituted by halogen or a C₁-C₂₀ hydrocarbyl group which may contain a heteroatom.

In a preferred embodiment, A¹, A² and A³ are each independently an acryloyloxy group, methacryloyloxy group, C₃-C₂₀ cycloalkenyl group which may contain a heteroatom, C₃-C₂₀ cycloalkenyloxy group which may contain a heteroatom, C₃-C₂₀ cycloalkenylcarbonyloxy group which may contain a heteroatom, C₂-C₂₀ alkenyl group which may contain a heteroatom, or C₂-C₂₀ alkenyloxy group which may contain a heteroatom.

A resist composition comprising the hypervalent bismuth compound defined herein and a solvent is also provided.

The resist composition may further comprise a radical scavenger and/or a surfactant.

In a further aspect, the invention provides a pattern forming process comprising the steps of applying the resist composition defined herein onto a substrate to form a resist film thereon, exposing the resist film to high-energy radiation, and developing the exposed resist film in an organic solvent developer to form a negative tone pattern in which the unexposed region is dissolved away and the exposed region is undissolved.

### Advantageous Effects of Invention

The resist composition exhibits both high sensitivity and resolution when processed by EB or EUV lithography, and is quite useful in micropatterning.

### DESCRIPTION OF EMBODIMENTS

The terms “a” and “an” herein do not denote a limitation of quantity, but rather denote the presence of at least one of the referenced item. As used herein, the notation (Cₙ-Cₘ) means a group containing from n to m carbon atoms per group.

The abbreviations and acronyms have the following meaning.
0 UV: ultraviolet radiation
EUV: extreme ultraviolet
EB: electron beam
Mw: weight average molecular weight
Mw/Mn: polydispersity index
GPC: gel permeation chromatography
PAB: post-apply bake
PEB: post-exposure bake
LWR: line width roughness
CDU: critical dimension uniformity

### Hypervalent Bismuth Compound

The hypervalent bismuth compound is a generic name for bismuth compounds having a valence electron formally exceeding the octet theory. One typical hypervalent bismuth compound is a five-coordinate bismuth compound having an oxidation number of +5.

The hypervalent bismuth compound of the invention is a five-coordinate hypervalent bismuth compound having the formula (1).

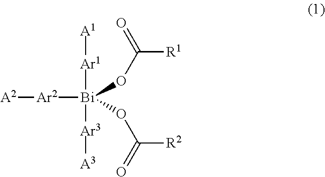

In formula (1), R¹ and R² are each independently halogen or a C₁-C₁₀ hydrocarbyl group which may contain a heteroatom. R¹ and R² may bond together to form a ring with the carbon atoms to which they are attached and the intervenient atoms.

Suitable halogen atoms include fluorine, chlorine, bromine and iodine.

The C₁-C₁₀ hydrocarbyl group may be saturated or unsaturated and straight, branched or cyclic. Examples thereof include C₁-C₁₀ alkyl groups such as methyl, ethyl, propyl, isopropyl, n-butyl, sec-butyl, tert-butyl, n-pentyl, tert-pentyl, n-hexyl, n-octyl, 2-ethylhexyl, n-nonyl, and n-decyl, C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, and adamantyl, C₂-C₁₀ alkenyl groups such as vinyl and 2-propenyl, C₆-C₁₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ and R² are preferably C₁-C₄ hydrocarbyl groups.

In formula (1), A¹, A² and A³ are each independently a C₂-C₂₀ hydrocarbyl group containing a polymerizable functional group. The hydrocarbyl group may contain a heteroatom.

Preferably, A¹, A² and A³ are each independently an acryloyloxy group, methacryloyloxy group, C₃-C₂₀ cycloalkenyl group which may contain a heteroatom, C₃-C₂₀ cycloalkenyloxy group which may contain a heteroatom, C₃-C₂₀ cycloalkenylcarbonyloxy group which may contain a heteroatom, C₂-C₂₀ alkenyl group which may contain a heteroatom, or C₂-C₂₀ alkenyloxy group which may contain a heteroatom.

Examples of the group represented by A¹, A² and A³ are shown below, but not limited thereto. The broken line designates a point of attachment to Ar¹, Ar² or Ar³.

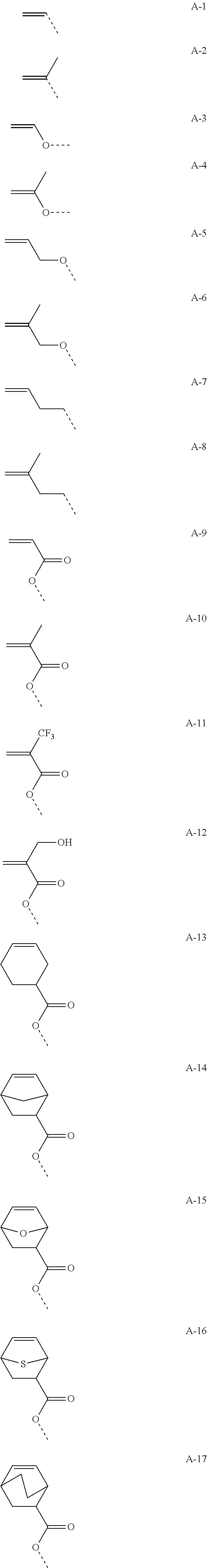

In formula (1), Ar¹, Ar² and Ar³ are each independently a C₆-C₂₀ arylene group in which some or all of the hydrogen atoms on an aromatic ring may be substituted by halogen or a C₁-C₂₀ hydrocarbyl group which may contain a heteroatom. Suitable arylene groups include phenylene, naphthylene and anthracenediyl. Each of Ar¹, Ar² and Ar³ is preferably phenylene or naphthylene, more preferably phenylene, most preferably 1,4-phenylene.

Examples of the hypervalent bismuth compound having formula (1) are shown below, but not limited thereto.

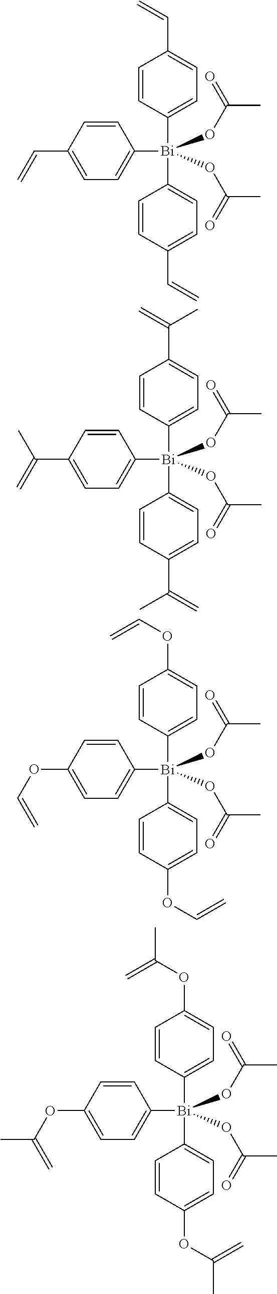

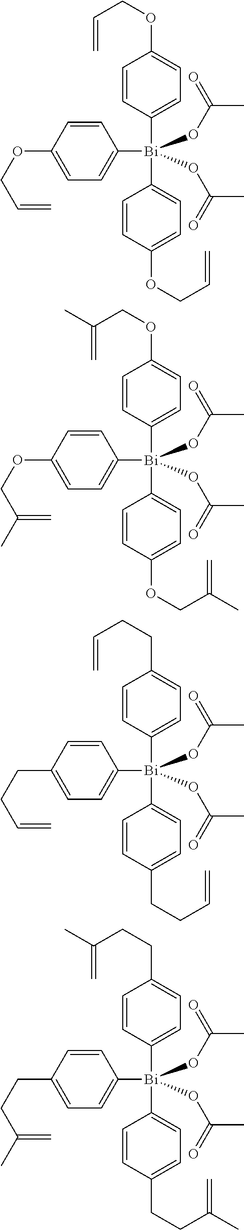

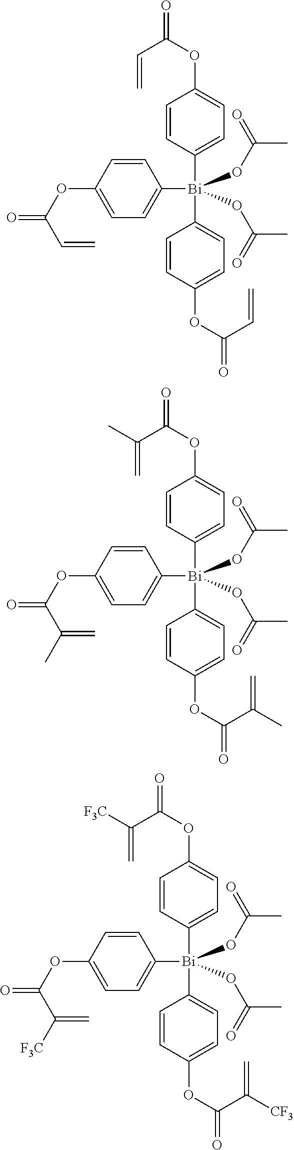

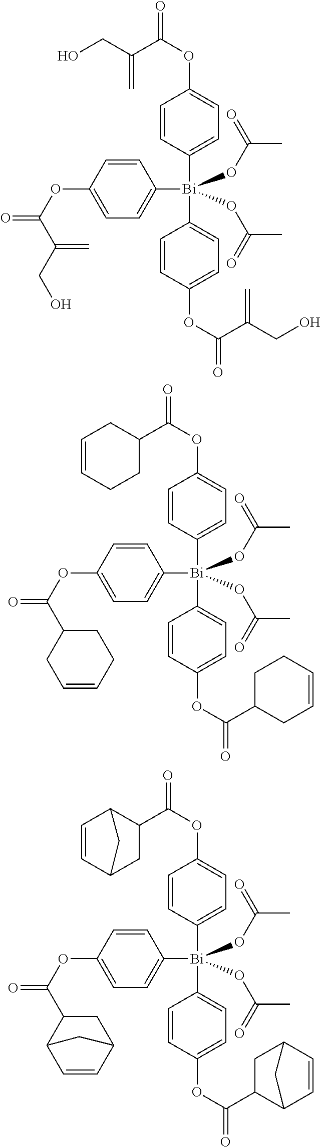

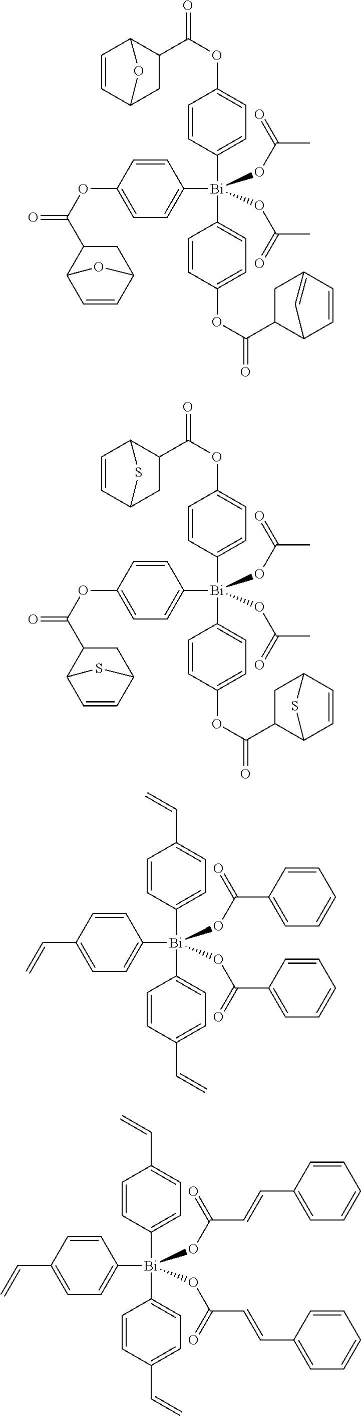

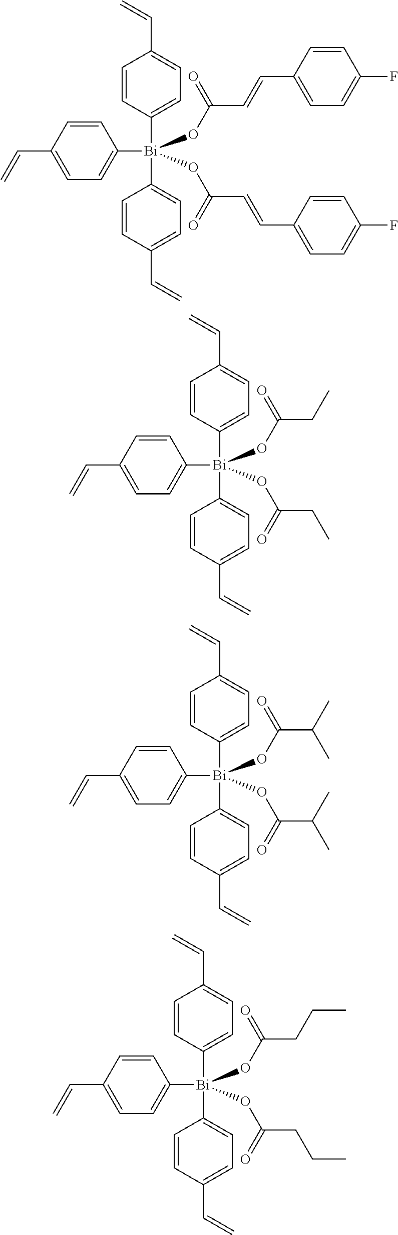

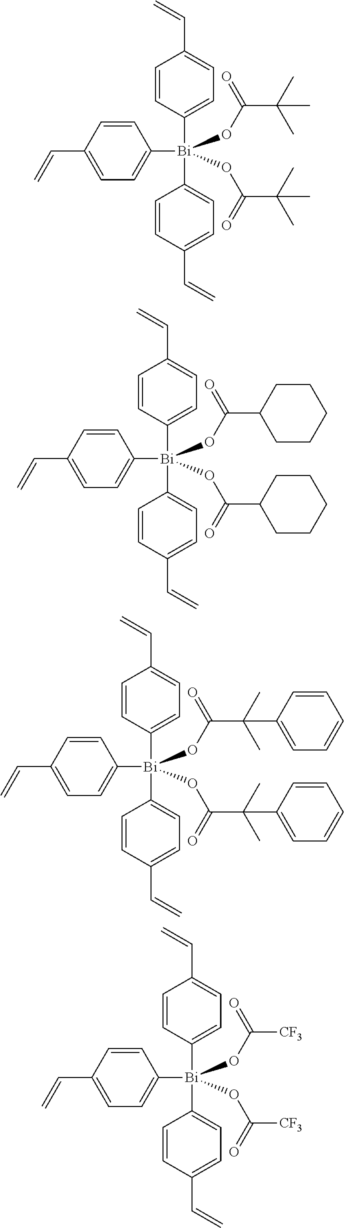

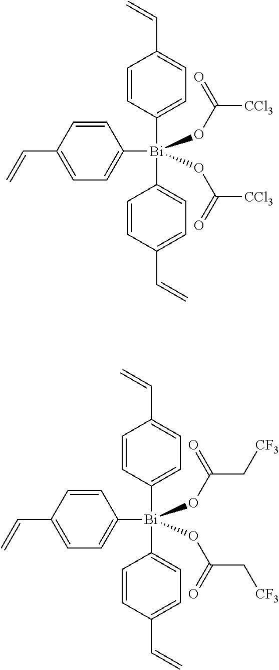

### Resist Composition

Another embodiment of the invention is a resist composition based on the hypervalent bismuth compound.

The resist composition further contains an organic solvent. The organic solvent is not particularly limited as long as the hypervalent bismuth compound is dissolvable therein and a film can be formed from the resulting solution. Suitable organic solvents include ketones such as cyclohexanone, methyl 2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids such as formic acid, acetic acid, and propionic acid; lactones such as γ-butyrolactone, and mixtures thereof.

The amount of the organic solvent is preferably 200 to 10,000 parts by weight per 100 parts by weight of overall solids in the composition. As used herein, the term “solids” is a general term for all components in the resist composition excluding the solvent. The organic solvent may be used alone or in admixture of two or more.

The resist composition may further contain a radical scavenger (or radical trapping agent). The radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpyperidine and 2,2,6,6-tetramethylpyperidine-N-oxy radical. Exemplary thiol compounds include dodecanethiol and hexadecanethiol. When used, the radical scavenger is preferably present in an amount of 0.01 to 10% by weight based on the overall solids. The radical scavenger may be used alone or in admixture.

The resist composition may further contain a surfactant. Exemplary surfactants include FC-4432 and FC-4430 (3M) and PF-636, PF-656, PF-632 and PF-6520 (Omnova Solutions, Inc.). When used, the amount of the surfactant is preferably 0.001 to 20 parts by weight, more preferably 0.1 to 10 parts by weight per 100 parts by weight of the hypervalent bismuth compound. The surfactant may be used alone or in admixture.

The resist composition contains the hypervalent bismuth compound as a main component, but not a polymer (or base polymer) containing an acid labile group and a photoacid generator as used in conventional chemically amplified resist compositions. The base polymer refers to a polymer which is present in resist compositions in the highest content among components other than the solvent, that is, main component. In a resist composition containing a base polymer, the base polymer is adapted to change its solubility in the developer under the action of acid generated by a PAG. Although the inventive resist composition does not contain a base polymer, the resist composition, when exposed to EB or EUV, undergoes a different change in solubility in the developer between exposed and unexposed regions so that a pattern may be formed. Although its mechanism is not well understood, the following mechanism is presumed.

The hypervalent bismuth compound having formula (1) is a five-coordinate compound having aryl groups and two carboxylate ligands bonded to the bismuth atom. When such a five-coordinate bismuth compound is exposed to EUV, the carboxy groups undergo radical dissociation to create carboxylate radicals, which in turn, cause the polymerizable group on aryl to undergo radical polymerization toward a higher molecular weight. Thus a robust resist film is formed.

After a resist film is formed on a substrate from the resist composition, the hypervalent bismuth compound as the main component is photo-decomposed in the exposure step to bring about a polarity switch. A negative pattern is formed in the subsequent development step.

From the above-mentioned presumption, the inventive resist composition is regarded as falling in the concept of non-chemically-amplified resist composition. Using the inventive resist composition, a small-size pattern can be resolved without the image blur due to acid diffusion as observed in conventional chemically-amplified resist compositions (i.e., compositions containing a base polymer and a PAG).

The inventive resist composition is quite effective in the EUV lithography. This is because a bismuth atom having a high absorptivity to EUV radiation is included. That is, shot noise is reduced, and higher resolution and lower LWR are achievable.

As the EUV lithography resist composition capable of forming a small size pattern, a metal resist composition based on a metal (specifically tin) compound having a high absorptivity to EUV radiation like bismuth atom is known, for example, from Patent Document 2. However, the metal resist composition suffers from many problems including a lack of solvent solubility and poor shelf stability. The inventive resist composition is improved in solvent solubility and has a wide range of application because it is applicable to negative tones.

### Pattern Forming Process

When the resist composition is used in the fabrication of various integrated circuits, any well-known lithography techniques are applicable. For example, the invention provides a pattern forming process comprising the steps of applying the resist composition onto a substrate to form a resist film on the substrate, exposing the resist film to high-energy radiation, and developing the exposed resist film in an organic solvent developer to form a negative tone pattern wherein the unexposed region is dissolved away and the exposed region is undissolved.

First, the resist composition is applied onto a substrate for integrated circuit fabrication (e.g., Si, SiO₂, SiN, SiON, TiN, WSi, BPSG, SOG, or organic antireflective coating), or a substrate for mask circuit fabrication (e.g., Cr, CrO, CrON, MoSi₂, or SiO₂) by any suitable technique such as spin coating, roll coating, flow coating, dip coating, spray coating or doctor coating. The coating is prebaked (PAB) on a hot plate at a temperature of preferably 60 to 200° C. for 10 seconds to 30 minutes, more preferably at 80 to 180° C. for 30 seconds to 20 minutes to form a resist film having a thickness of 0.01 to 2 μm.

Next the resist film is exposed to high-energy radiation. The radiation is selected from among UV, deep-UV, EB, EUV, X-ray, soft X-ray, excimer laser radiation, γ-ray, and synchrotron radiation. On use of UV, deep-UV, EUV, X-ray, soft X-ray, excimer laser radiation, γ-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 5,000 μC/cm², more preferably about 0.5 to 4,000 μC/cm². The resist composition is best suited in micropatterning using EB or EUV as the high-energy radiation.

If necessary, the resist film is post-exposure baked (PEB). Preferably PEB is performed on a hot plate or in an oven at 30 to 200° C. for 10 seconds to 30 minutes, more preferably at 60 to 100° C. for 30 seconds to 20 minutes.

After the exposure or PEB, the resist film is developed in an organic solvent developer to form a negative tone pattern wherein the unexposed region is dissolved away and the exposed region is undissolved. Examples of the organic solvent as developer include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, isopropyl alcohol, n-butanol, n-pentanol, propyl acetate, butyl acetate, isobutyl acetate, pentyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, diacetone alcohol, and 4-methyl-2-pentanol. These organic solvents may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Water may also be used instead of the organic solvent.

Rinsing is effective for preventing the resist pattern from collapse or reducing defect formation. Rinsing is not essential. By omitting rinsing, the amount of the solvent used is saved.

### EXAMPLES

Examples of the invention are given below by way of illustration and not by way of limitation. The abbreviation “pbw” is parts by weight.

### [1] Synthesis of Hypervalent Bismuth Compounds

### Synthesis Example 1

### Synthesis of Hypervalent Bismuth Compound B-1

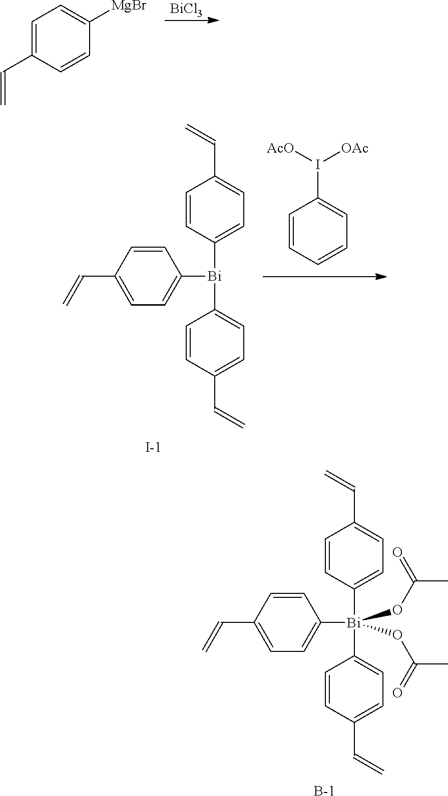

In nitrogen atmosphere, 22.91 g (72.66 mmol) of bismuth (III) chloride was dispersed in 100 mL of THF. The dispersion was cooled at 0° C., 109 mL (218 mmol) of 2.0 M 4-vinylphenylmagnesium bromide was added dropwise. The dispersion was stirred for 1 hour at the temperature. While the dispersion was heated under reflux, it was stirred for a further 2 hours. At the end of reaction, under ice cooling, 200 mL of saturated ammonium chloride aqueous solution was added, followed by extraction with 500 mL of toluene. The organic layer was washed 3 times with 200 mL of deionized water, and the solvent was distilled off. The residue was purified by silica gel column chromatography using hexane as the developing solvent, obtaining Intermediate I-1 as white crystals (amount 24.83 g, yield 77.6%). Intermediate I-1 was analyzed by NMR spectroscopy.

¹H-NMR (500 MHZ, CDCl₃, δ in ppm):

7.70 (d, J-8.0 Hz, 6H), 7.41 (d, J-8.0 Hz, 6H), 6.68 (dd, J-17.1 and 11.4 Hz, 3H),

5.75 (dd, J=17.1 and 1.1 Hz, 3H), 5.23 (dd, J=11.4 and 1.1 Hz, 3H)

In 70 g of methylene chloride, 7 g (13.50 mmol) of Intermediate I-1 was dispersed. 4.34 g (13.50 mmol) of (diacetoxyiodo) benzene (DAIB) was added to the dispersion, which was stirred at room temperature for 12 hours. Once the solvent was distilled off, 100 mL of hexane was added to the residue, which was stirred at room temperature for 1 hour. The solids were collected by filtration and dried at 40° C., obtaining hypervalent bismuth compound B-1 as white crystals (amount 4.82 g, yield 63.7%). Hypervalent bismuth compound B-1 was analyzed by NMR spectroscopy and mass spectrometry (MS).

¹H-NMR (500 MHz, CDCl₃, δ in ppm):

8.18 (d, J=8.0 Hz, 6H), 7.59 (d, J-8.0 Hz, 6H), 6.71 (dd, J=17.7 and 10.9 Hz, 3H),

5.81 (dd, J=17.7 and 0.9 Hz, 3H), 5.32 (dd, J=10.9 and 0.9 Hz, 3H), 1.75 (s, 6H)

Single quadrupole MS (ESI): positive M⁺Na⁺659 (corresponding to C₂₈H₂₇BiNaO₄)

### Synthesis Example 2

### Synthesis of Hypervalent Bismuth Compound B-2

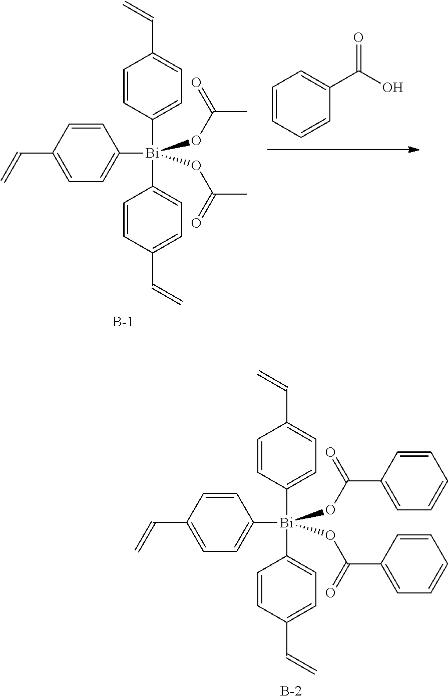

In 5 g of methyl 2-hydroxyisobutyrate (HBM), 0.6 g (0.94 mmol) of hypervalent bismuth compound B-1 was dispersed. 0.23 g (1.88 mmol) of benzoic acid was added to the dispersion, which was stirred at 60° C. for 12 hours. Once the solvent was distilled off, 30 mL of methanol was added to the residue, which was stirred at room temperature for 1 hour. The solids were collected by filtration and dried at 40° C., obtaining hypervalent bismuth compound B-2 as white crystals (amount 0.48 g, yield 84.9%). Hypervalent bismuth compound B-2 was analyzed by NMR and MS.

¹H-NMR (500 MHZ, CDCl₃, δ in ppm):

8.24 (d, J-8.2 Hz, 6H), 8.02 (m, 4H), 7.62 (d, J=8.2 Hz, 6H), 7.32 (m, 6H),

6.66 (dd, J=17.5 and 10.5 Hz, 3H), 5.74 (dd, J=17.5 and 0.9 Hz, 3H),

5.35 (dd, J=10.5 and 0.9 Hz, 3H)

Single quadrupole MS (ESI): positive M⁺Na⁺783 (corresponding to C₃₈H₃₁BiNaO₄)

### Synthesis Example 3

### Synthesis of Hypervalent Bismuth Compound B-3

Hypervalent bismuth compound B-3 was synthesized by the same procedure as in Synthesis Examples 1 and 2 aside from changing the starting reactants.

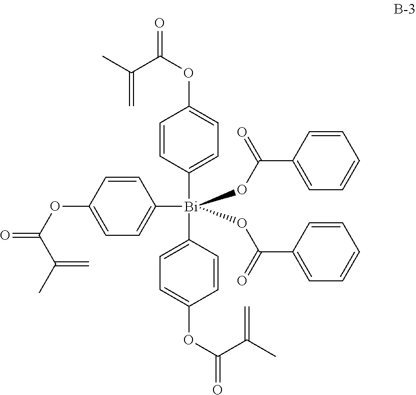

### [2] Preparation of Resist Composition

### Examples 1-1 to 1-6 and Comparative Examples 1-1 to 1-5

Resist compositions (R-01 to R-06, CR-01 and CR-02) were prepared by dissolving a hypervalent bismuth compound in a solvent in accordance with the recipe shown in Table 1, and filtering the solution through a Teflon® filter having a pore size of 0.2 μm. Also, resist compositions (CR-03 to CR-05) were prepared by mixing a polymer, a photoacid generator, a sensitivity modifier, a solvent, and 0.01 wt % of a surfactant (PF-636, Omnova Solutions, Inc.) in accordance with the recipe shown in Table 2, and filtering the solution through a Teflon® filter having a pore size of 0.2 μm.

TABLE 1

| | | | Hypervalent | | |
|---|---|---|---|---|---|
| | | | bismuth | | |
| | | Resist | compound | Solvent 1 | Solvent 2 |
| | | composition | (pbw) | (pbw) | (pbw) |
| Example | 1-1 | R-01 | B-1 (14.0) | PGMEA (900) | GBL (100) |
| | 1-2 | R-02 | B-1 (14.0) | HBM (1000) | — |
| | 1-3 | R-03 | B-2 (15.4) | PGMEA (900) | GBL (100) |
| | 1-4 | R-04 | B-2 (15.4) | HBM (1000) | — |
| | 1-5 | R-05 | B-3 (14.0) | PGMEA (900) | GBL (101) |
| | 1-6 | R-06 | B-3 (14.0) | HBM (1000) | — |
| Comparative | 1-1 | CR-01 | O-1 (14.0) | HBM (1000) | — |
| Example | 1-2 | CR-02 | O-2 (14.0) | HBM (1000) | — |

TABLE 2

| | | | Base | | Sensitivity | | |
|---|---|---|---|---|---|---|---|
| | | Resist | polymer | PAG | modifier | Solvent 1 | Solvent 2 |
| | | composition | (pbw) | (pbw) | (pbw) | (pbw) | (pbw) |
| Comparative | 1-3 | CR-03 | P-1 (80) | PAG-1 (19.0) | Q-1 (6.2) | PGMEA (1890) | GBL (210) |
| Example | 1-4 | CR-04 | P-1 (80) | PAG-2 (21.0) | Q-1 (6.2) | PGMEA (1890) | GBL (210) |
| | 1-5 | CR-05 | P-1 (80) | PAG-1 (19.0) | Q-2 (2.6) | PGMEA (1890) | GBL (210) |

In Tables 1 and 2, the organic solvent, hypervalent bismuth compound (0-1 and O-2), base polymer (P-1), photoacid generator (PAG-1 and PAG-2), and sensitivity modifier (Q-1 and Q-2) are identified below.

### Solvent:

PGMEA (propylene glycol monomethyl ether acetate)
HBM (methyl 2-hydroxyisobutyrate)
GBL (γ-butyrolactone)

Hypervalent bismuth compound: 0-1 and O-2

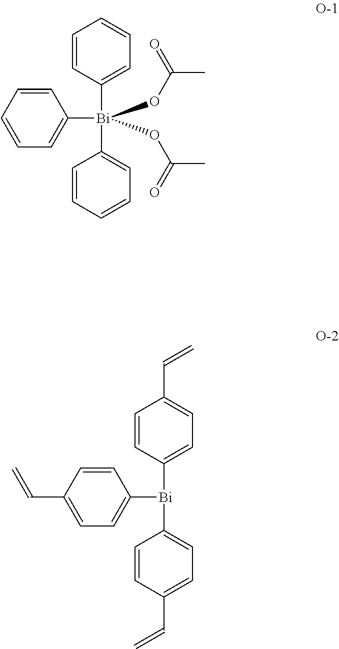

Base polymer: P-1

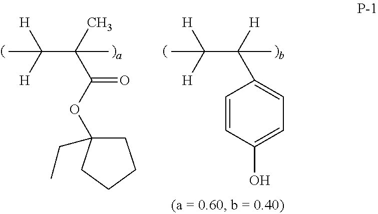

Mw=8755 (vs polystyrene), Mw/Mn=1.94

Photoacid generator: PAG-1 and PAG-2

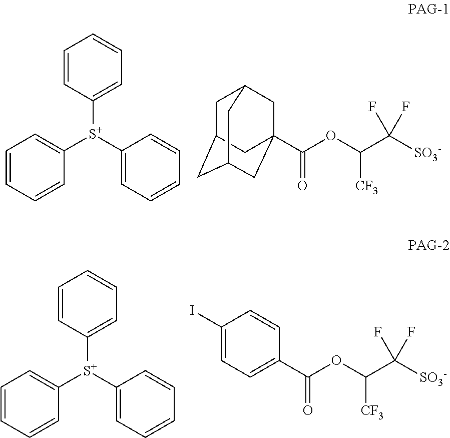

Sensitivity modifier: Q-1 and Q-2

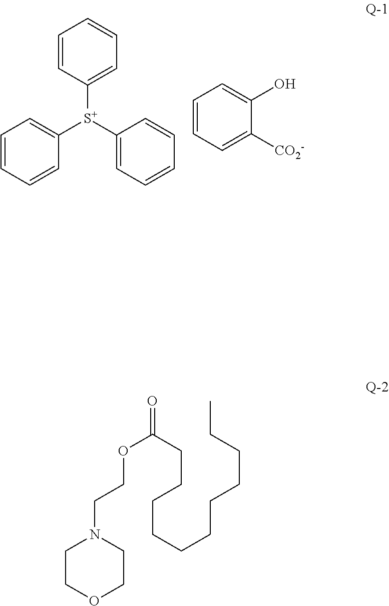

[3] EUV lithography test (line-and-space pattern, negative tone development)

### Examples 2-1 to 2-6 and Comparative Examples 2-1 to 2-5

Each of the resist compositions (R-01 to R-06, CR-01 to CR-05) was spin coated on a silicon substrate having a 20-nm coating of silicon-containing spin-on hard mask SHB-A940 (Shin-Etsu Chemical Co., Ltd., silicon content 43 wt %) and prebaked (PAB) on a hotplate at the temperature shown in Table 3 for 60 seconds to form a resist film of 40 nm thick. Using an EUV scanner NXE3400 (ASML, NA 0.33, σ 0.9, 90° dipole illumination), the resist film was exposed to EUV through a mask bearing a 48-nm 1:1 line-and-space (LS) pattern. The resist film was baked (PEB) on a hotplate at the temperature shown in Table 3 for 60 seconds and developed in the developer shown in Table 3 for 30 seconds to form a LS pattern having a space width of 24 nm and a pitch of 48 nm.

The LS pattern was observed under CD-SEM (CG-6300, Hitachi High-Technologies Corp.) and evaluated for sensitivity, LWR and maximum resolution by the following methods. The results are also shown in Table 3.

### [Evaluation of Sensitivity]

The optimum dose Eop (mJ/cm²) which provided an LS pattern with a space width of 24 nm and a pitch of 48 nm was determined and reported as sensitivity.

### [Evaluation of LWR]

An LS pattern was formed by exposure in the optimum dose (Eop). The space width was measured at longitudinally spaced apart 10 points, from which a 3-fold value (3σ) of the standard deviation (6) was determined and reported as LWR. A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

TABLE 3

| | | | | | | | Maximum |
|---|---|---|---|---|---|---|---|
| | | Resist | PAB/PEB | | Eop | LWR | resolution |
| | | composition | (° C.) | Developer | (mJ/cm²) | (nm) | (nm) |
| Example | 2-1 | R-01 | 120/80 | nBA | 60 | 3.4 | 18 |
| | 2-2 | R-02 | 120/80 | nBA | 61 | 3.7 | 20 |
| | 2-3 | R-03 | 120/80 | nBA | 64 | 3.9 | 21 |
| | 2-4 | R-04 | 120/80 | nBA | 58 | 3.7 | 21 |
| | 2-5 | R-05 | 120/80 | nBA | 60 | 3.6 | 19 |
| | 2-6 | R-06 | 120/80 | nBA | 60 | 3.8 | 20 |
| Comparative | 2-1 | CR-01 | 120/80 | nBA | 78 | 4.6 | 25 |
| Example | 2-2 | CR-02 | 120/80 | nBA | 85 | 4.8 | 25 |
| | 2-3 | CR-03 | 105/90 | nBA | 73 | 4.8 | 24 |
| | 2-4 | CR-04 | 105/90 | nBA | 83 | 4.7 | 24 |
| | 2-5 | CR-05 | 105/90 | nBA | 73 | 4.8 | 24 |

Developer: nBA (n-butyl acetate)

It is evident from Table 3 that the LS patterns formed from the resist compositions within the scope of the invention by EUV lithography are excellent in sensitivity, LWR and resolution even in the case of negative tone development.

[4] EUV lithography test (contact hole pattern)

### Examples 3-1 to 3-6 and Comparative Examples 3-1 to 3-5

Each of the resist compositions (R-01 to R-06, CR-01 to CR-05) was spin coated on a silicon substrate having a 20-nm coating of silicon-containing spin-on hard mask SHB-A⁹⁴⁰ (Shin-Etsu Chemical Co., Ltd., a silicon content of 43 wt %) and prebaked (PAB) on a hotplate at the temperature shown in Table 4 for 60 seconds to form a resist film of 50 nm thick. Using an EUV scanner NXE3400 (ASML, NA 0.33, σ 0.9/0.6, quadrupole illumination), the resist film was exposed to EUV through a mask bearing a hole pattern with a pitch of 64 nm+20% bias (on-wafer size). After exposure, the resist film was baked (PEB) on a hotplate at the temperature shown in Table 4 for 60 seconds and developed in the developer shown in Table 4 for 30 seconds to form a contact hole (CH) pattern having a size of 32 nm.

The CH pattern was observed under CD-SEM (CG-6300, Hitachi High-Technologies Corp.) and evaluated for sensitivity, CDU and maximum resolution by the following methods. The results are also shown in Table 4.

### [Evaluation of Sensitivity]

The optimum dose Eop (mJ/cm²) which provided a CH pattern with a size of 32 nm was determined and reported as sensitivity.

### [Evaluation of CDU]

The size of 50 holes which were printed at Eop was measured, from which a 3-fold value (3σ) of the standard deviation (o) was computed and reported as CDU. A smaller value of CDU indicates a CH pattern with more uniform hole diameter.

### [Evaluation of Maximum Resolution]

A CH pattern was formed while reducing the exposure dose little by little from the optimum dose (Eop). The hole diameter (nm) which could be resolved was determined and reported as maximum resolution. A smaller value indicates a pattern having a better maximum resolution and smaller hole diameter.

TABLE 4

| | | | | | | | Maximum |
|---|---|---|---|---|---|---|---|
| | | Resist | PAB/PEB | | Eop | CDU | resolution |
| | | composition | (° C.) | Developer | (mJ/cm²) | (nm) | (nm) |
| Example | 3-1 | R-01 | 120/80 | IPA | 38 | 2.7 | 28 |
| | 3-2 | R-02 | 120/80 | IPA | 41 | 2.9 | 29 |
| | 3-3 | R-03 | 120/80 | IPA | 41 | 3.0 | 27 |
| | 3-4 | R-04 | 120/80 | IPA | 43 | 2.9 | 29 |
| | 3-5 | R-05 | 120/80 | IPA | 43 | 2.9 | 30 |
| | 3-6 | R-06 | 120/80 | IPA | 42 | 2.9 | 28 |
| Comparative | 3-1 | CR-01 | 120/80 | IPA | 42 | 3.0 | 29 |
| Example | 3-2 | CR-02 | 120/80 | IPA | 44 | 3.1 | 28 |
| | 3-3 | CR-03 | 105/90 | TMAH | 48 | 3.8 | 33 |
| | 3-4 | CR-04 | 105/90 | TMAH | 45 | 3.9 | 34 |
| | 3-5 | CR-05 | 105/90 | TMAH | 51 | 3.9 | 33 |

Developer: IPA (isopropyl alcohol)
TMAH (2.38 wt % aqueous solution of tetramethylammonium hydroxide)

It is evident from Table 4 that the CH patterns formed from the resist compositions within the scope of the invention by EUV lithography are excellent in sensitivity, CDU and resolution.

Japanese Patent Application No. 2024-140590 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A hypervalent bismuth compound having the formula (1): 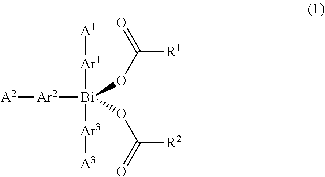
wherein R¹ and R² are each independently halogen or a C₁-C₁₀ hydrocarbyl group which may contain a heteroatom, R¹ and R² may bond together to form a ring with the carbon atoms to which they are attached and the intervenient atoms,
A¹, A² and A³ are each independently a C₂-C₂₀ hydrocarbyl group which contains a polymerizable functional group and may contain a heteroatom,
Ar¹, Ar² and Ar³ are each independently a C₆-C₂₀ arylene group in which some or all of the hydrogen atoms on an aromatic ring may be substituted by halogen or a C₁-C₂₀ hydrocarbyl group which may contain a heteroatom.

2. The hypervalent bismuth compound of claim 1 wherein A¹, A² and A³ are each independently an acryloyloxy group, methacryloyloxy group, C₃-C₂₀ cycloalkenyl group which may contain a heteroatom, C₃-C₂₀ cycloalkenyloxy group which may contain a heteroatom, C₃-C₂₀ cycloalkenylcarbonyloxy group which may contain a heteroatom, C₂-C₂₀ alkenyl group which may contain a heteroatom, or C₂-C₂₀ alkenyloxy group which may contain a heteroatom.

3. A resist composition comprising the hypervalent bismuth compound of claim 1 and a solvent.

4. The resist composition of claim 3, further comprising a radical scavenger.

5. The resist composition of claim 3, further comprising a surfactant.

6. A pattern forming process comprising the steps of applying the resist composition of claim 3 onto a substrate to form a resist film thereon, exposing the resist film to high-energy radiation, and developing the exposed resist film in an organic solvent developer to form a negative tone pattern in which the unexposed region is dissolved away and the exposed region is undissolved.
